(19) United States
(12) Patent Application Publication
(10) Pub. No.: US 2026/0040793 A1
(43) Pub. Date: Feb. 5, 2026

(54) DISPLAY DEVICE, METHOD FOR MANUFACTURING THE SAME, AND PORTABLE ELECTRONIC DEVICE

(71) Applicant: SAMSUNG DISPLAY CO., LTD., YONGIN-SI (KR)

(72) Inventors: Shinya ONOUE, Yongin-si (KR); Jong Deok PARK, Yongin-si (KR); Jae Young SIM, Yongin-si (KR); So Yeon JOO, Yongin-si (KR); Hyeon Deuk HWANG, Yongin-si (KR)

(21) Appl. No.: 19/078,709

(22) Filed: Mar. 13, 2025

(30) Foreign Application Priority Data
Jul. 30, 2024 (KR) 10-2024-0101031

(51) Int. Cl. H10K 59/80; C08K 5/09; C08K 5/52; H10K 59/12; H10K 59/40

(52) U.S. Cl. CPC H10K 59/8722; C08K 5/09; C08K 5/52; H10K 59/1201; H10K 59/40; H10K 59/8792

(57) ABSTRACT

A display device, a method for manufacturing the display device, and a portable electronic device are provided. The display device includes a display module, the display module including a display panel, a driver substrate connected to the display module, a bending protection layer disposed on one surface of the display panel, and an outer structure surrounding the driver substrate and the bending protection layer, in which a filler composition for fabricating the outer structure includes a cationic polymerizable compound, a cationic photopolymerization initiator, and at least one selected from a phosphoric compound or a carboxylic acid compound.

### CROSS-REFERENCE TO RELATED APPLICATION

This application claims priority under 35 U.S.C. § 119 to Korean Patent Application No. 10-2024-0101031, filed on Jul. 30, 2024, in the Korean Intellectual Property Office, the contents of which are herein incorporated by reference in their entirety.

### TECHNICAL FIELD

The present disclosure relates to a display device, a method for manufacturing a display device, and a portable electronic device.

### DISCUSSION OF RELATED ART

As the information society develops, the demand for display devices for displaying images is increasing in various forms. The display devices may be flat-panel display devices such as, for example, liquid crystal display (LCD) devices, plasma display (PD) devices, field-emission display (FED) devices, or light-emitting display devices. The light-emitting display devices do not require an additional external light source, so that the brightness and color can be controlled independently for each pixel, therefore capable of obtaining an infinite contrast ratio and producing true blacks and more vivid colors. Examples of the light-emitting display devices include organic light-emitting display devices that include organic light-emitting diodes (OLEDs) as light-emitting elements and inorganic light-emitting display devices that include inorganic light-emitting diodes (LEDs) as light-emitting elements.

To enhance aesthetics, flexible display devices with bendable edge portions that achieve a certain curvature have emerged. The flexible display devices including, for example, the light-emitting display devices, are increasingly being adopted and used in portable electronic devices. Accordingly, research on fillers that protect these edge portions has been actively conducted.

### SUMMARY

Embodiments of the present disclosure provide a display device, a method for manufacturing the display device, and a portable electronic device that prevents uncuring of an outer structure at the interface with a bending protection layer. However, the embodiments of the present disclosure are not restricted to those set forth herein, and will become more apparent to one of ordinary skill in the art to which the present disclosure pertains by referencing the detailed description of the present disclosure given below.

According to an embodiment of the present disclosure, a display device includes a display module, the display module including a display panel, a driver substrate connected to the display module, a bending protection layer disposed on one surface of the display panel, and an outer structure surrounding the driver substrate and the bending protection layer, in which a filler composition for fabricating the outer structure includes a cationic polymerizable compound, a cationic photopolymerization initiator, and at least one selected from a phosphoric compound or a carboxylic acid compound.

In an embodiment of the present disclosure, the cationic polymerizable compound includes a cyclic compound having an epoxy group and an aromatic compound having an epoxy group.

In an embodiment of the present disclosure, the aromatic compound having an epoxy group includes a bisphenol A-type epoxy resin and a bisphenol F-type epoxy resin.

In an embodiment of the present disclosure, a mass ratio of the bisphenol A-type epoxy resin to the bisphenol F-type epoxy resin is from about 0.2 to about 5.

In an embodiment of the present disclosure, the phosphoric compound includes at least one selected from among compounds represented by Chemical Formulas 1 through 4:

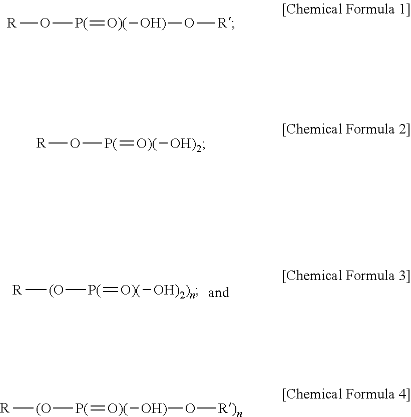

wherein R and R′ are each independently a substituted or unsubstituted hydrocarbon group, and n is from 2 to 10.

In an embodiment of the present disclosure, the carboxylic acid compound includes at least one selected from among compounds represented by Chemical Formulas 5 and 6:

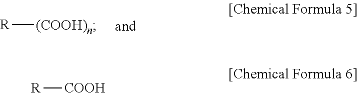

wherein R is each independently a substituted or unsubstituted hydrocarbon group, and n is from 2 to 10.

In an embodiment of the present disclosure, the phosphoric compound or the carboxylic acid compound is included in an amount of about 0.1 to about 5 parts by mass per 100 parts by mass of the cationic polymerizable compound.

In an embodiment of the present disclosure, the cationic photopolymerization initiator includes at least one selected from among a sulfonium salt, an iodonium salt, or an onium salt other than the sulfonium salt and the iodonium salt.

In an embodiment of the present disclosure, the cationic photopolymerization initiator is included in an amount of about 0.05 to about 50 parts by mass per 100 parts by mass of the cationic polymerizable compound.

In an embodiment of the present disclosure, the phosphoric compound includes a phosphoric ester, and a molecular weight of the phosphoric ester is about 400 or less.

In an embodiment of the present disclosure, a viscosity of the filler composition is from about 1,000 cps to about 20,000 cps.

According to an embodiment of the present disclosure, a method for manufacturing a display device that includes a display module including a display panel, a driver substrate connected to the display module, and a bending protection layer disposed on one surface of the display panel, the method includes combining a mold unit and the display device, injecting a paste through an inlet of the mold unit, and curing the paste to form an outer structure, in which the paste includes a cationic polymerizable compound, a cationic photopolymerization initiator, and at least one selected from a phosphoric compound or a carboxylic acid compound.

In an embodiment of the present disclosure, the paste is photo-cured.

In an embodiment of the present disclosure, the photo-curing of the paste is performed for about 30 seconds to about 1 minute.

In an embodiment of the present disclosure, the paste contacts the bending protection layer.

In an embodiment of the present disclosure, the cationic polymerizable compound includes a cyclic compound having an epoxy group and an aromatic compound having an epoxy group.

In an embodiment of the present disclosure, the aromatic compound having an epoxy group includes a bisphenol A-type epoxy resin and a bisphenol F-type epoxy resin, and a mass ratio of the bisphenol A-type epoxy resin to the bisphenol F-type epoxy resin is from about 0.2 to about 5.

In an embodiment of the present disclosure, the phosphoric compound includes at least one selected from among compounds represented by Chemical Formulas 1 through 4:

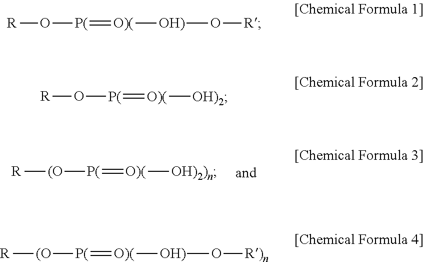

wherein R and R′ are each independently a substituted or unsubstituted hydrocarbon group, and n is from 2 to 10.

In an embodiment of the present disclosure, the carboxylic acid compound includes at least one selected from among compounds represented by Chemical Formulas 5 and 6:

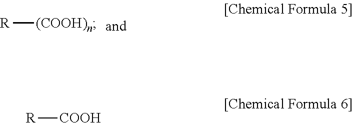

wherein R is each independently a substituted or unsubstituted hydrocarbon group, and n is from 2 to 10.

In an embodiment of the present disclosure, the phosphoric compound or the carboxylic acid compound is included in an amount of about 0.1 to about 5 parts by mass per 100 parts by mass of the cationic polymerizable compound.

According to an embodiment of the present disclosure, an electronic device includes a processor, a memory having stored application programs for execution by the processor, a display device including a display panel and receiving data from the processor to display image, and a user interface configured to sense user input via touch or cursor select of an icon presented on the display panel, in which the processor is caused to execute one or more of the stored application programs upon receipt of the user input. The display device includes a display module, the display module including the display panel, a driver substrate connected to the display module, a bending protection layer disposed on one surface of the display panel, and an outer structure surrounding the driver substrate and the bending protection layer. in which a filler composition for fabricating the outer structure includes a cationic polymerizable compound, a cationic photopolymerization initiator, and at least one selected from a phosphoric compound or a carboxylic acid compound.

In an embodiment of the present disclosure, the stored application programs include one or more of a camera application, an audiovisual streaming application, or a telephone application.

In an embodiment of the present disclosure, the user interface is a touch screen embedded in the display panel, in which the touch screen includes touch sensors for sensing a touch or a tap by a user.

In an embodiment of the present disclosure, the user interface includes an audio sensor embedded in the display panel, in which the audio sensor is configured to receive voice commands to cause access to one or more of the application programs.

According to the aforementioned and other embodiments of the present disclosure, by including at least one selected from among a cationic polymerizable compound, a cationic photopolymerization initiator, a phosphoric compound, or a carboxylic acid compound, photo-curing inhibition by the amine of the protective layer or cover panel may be prevented. Accordingly, uncuring of the outer structure formed by the filler composition may be avoided.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the accompanying drawings, in which:

FIG. 1 is a schematic perspective view of an electronic device according to an embodiment of the present disclosure;

FIG. 2 is a schematic perspective view of the display device according to an embodiment of the present disclosure;

FIG. 3 is a schematic cross-sectional view taken along line X1-X1′ of FIG. 2;

FIG. 4 is a schematic cross-sectional view illustrating a stack structure of a display module according to an embodiment of the present disclosure;

FIG. 5 is a schematic cross-sectional view illustrating an electronic device according to an embodiment of the present disclosure;

FIG. 6 is an enlarged cross-sectional view of area A of FIG. 4;

FIG. 7 is a flowchart illustrating a method for manufacturing an electronic device according to an embodiment of the present disclosure;

FIG. 8 is a cross-sectional view illustrating step S100 of FIG. 7;

FIG. 9 is a cross-sectional view illustrating step S200 of FIG. 7;

FIG. 10 is an enlarged cross-sectional view of area E of FIG. 9;

FIG. 11 is a cross-sectional view illustrating step S300 of FIG. 7;

FIG. 12 is a cross-sectional view illustrating step S400 of FIG. 7;

FIG. 13 is a cross-sectional view illustrating step S500 of FIG. 7;

FIG. 14 is a cross-sectional view illustrating step S600 of FIG. 7; and

FIG. 15 is a diagram illustrating an electronic device according to an embodiment of the present disclosure.

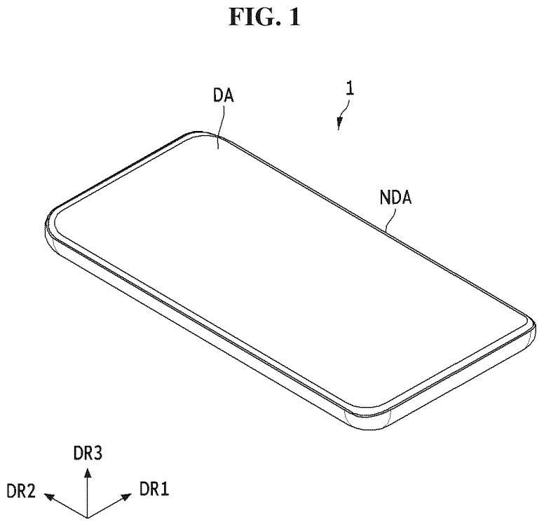

Since the drawings in FIGS. 1-15 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will be understood that when a layer is referred to as being “on” another layer or substrate, it may be directly on the other layer or substrate, or intervening layers may also be present. The same reference numerals indicate the same components throughout the specification.

It will also be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Each of the features of the various embodiments of the present disclosure may be combined or combined with each other, in part or in whole, and technically various interlocking and driving are possible. Each embodiment may be implemented independently of each other or may be implemented together in an association.

Embodiments of the present disclosure will be described with reference to the accompanying drawings.

FIG. 1 is a schematic perspective view of an electronic device according to an embodiment of the present disclosure.

Referring to FIG. 1, an electronic device 1 displays a moving image or a still image. The electronic device 1 may refer to any electronic device that provides a display screen. For example, a television (TV), a laptop, a monitor, a billboard, an Internet of Things (IoT) device, a mobile phone, a smartphone, a tablet personal computer (PC), an electronic watch, a smartwatch, a watchphone, a glasses-type display, a head-mounted display (HMD), a mobile communication terminal, an electronic notebook, an e-book reader, a portable multimedia player (PMP), a navigation device, an ultra mobile PC (UMPC), a gaming console, a digital camera, a camcorder, and the like may be included in the display device 10. For example, the electronic device 1 may be a portable electronic device including the display device 10. In addition, the display device 10 according to an embodiment of the present disclosure may be used as a display in an instrument panel of a vehicle and a center information display (CID) arranged on a center fascia or a dashboard of a vehicle, a room mirror display for replacing side-view mirrors of a vehicle, or a display arranged on a rear surface of a front seat for providing entertainment content to a passenger in a back seat of a vehicle.

The electronic device 1 may include a display device 10 that provides a display screen. Examples of the display device 10 may include, for example, an inorganic light-emitting diode display device, an organic light-emitting display device, a quantum dot light-emitting display device, a micro light-emitting diode (LED) display device, or a nano LED display device, a plasma display (PD) device, and a field-emission display (FED) device. An organic light-emitting display device will hereinafter be exemplified as the display device 10, but the present disclosure is not limited thereto. Other display devices may also be applicable if the same technical idea of the present disclosure may be applied.

The shape of the electronic device 1 may vary. For example, the electronic device 1 may have the shape of a horizontally elongated rectangle, a vertically elongated rectangle, a square, a rectangle with rounded corners, another polygon other than quadrilaterals with or without rounded corners, an oval, or a circle. The shape of a display area DA of the electronic device 1 may be similar to the overall shape of the electronic device 1. In FIG. 1, an electronic device 1 in the shape of an elongated rectangle in a second direction DR2 is illustrated.

The electronic device 1 may include the display area DA and a non-display area NDA. The display area DA is the area where a screen may be displayed, and the non-display area NDA is the area where the screen is not displayed. The display area DA may also be referred to as an active area, and the non-display area NDA may also be referred to as an inactive area. The display area DA may generally occupy the center of the electronic device 1.

The non-display area NDA may be disposed around the display area DA. The non-display area NDA may be a bezel area. The bezel area may have a relatively low light transmittance compared to a transmissive area, and may include an opaque material that blocks a light. The non-display area NDA may surround the display area DA, but the present disclosure is not limited thereto. Alternatively, for example, the non-display area NDA may not be present in at least some of the surrounding areas of the display area DA. For example, the non-display area NDA may be arranged adjacent to only one side of the display area DA, or may not be provided. Signal wirings or driving circuits for applying signals to the display area DA or touch area may be disposed in the non-display area NDA. Alternatively, in an embodiment of the present disclosure, the non-display area NDA may include some touch areas, and sensor members such as pressure sensors may be disposed in these touch areas.

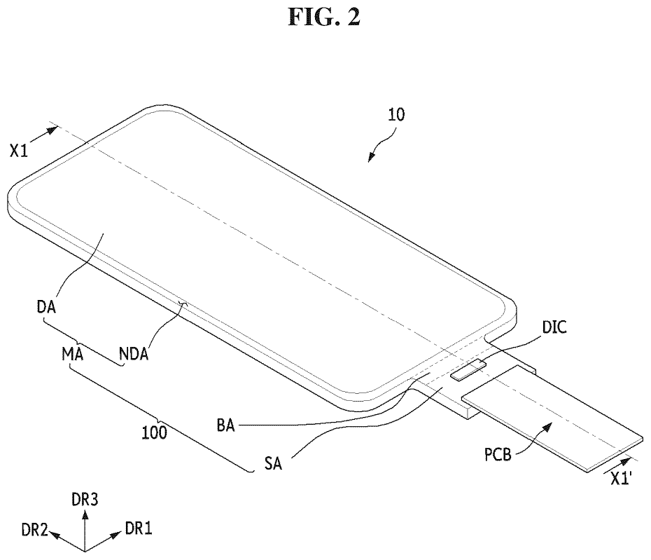

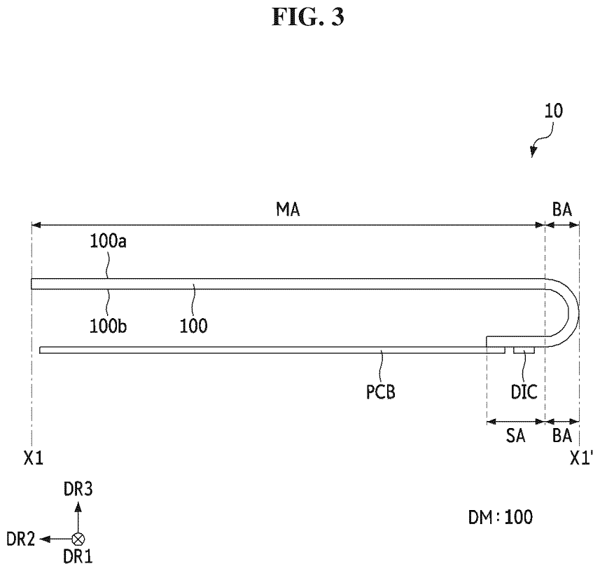

FIG. 2 is a schematic perspective view of the display device according to an embodiment of the present disclosure. FIG. 3 is a schematic cross-sectional view taken along line X1-X1′ of FIG. 2.

Referring to FIGS. 2 and 3, the electronic device 1 may include the display device 10. The display device 10 may provide the screen displayed by the electronic device 1. The display device 10 may have a planar shape similar to that of the electronic device 1. For example, the display device 10 may have a shape similar to a rectangle with short sides in a first direction DR1 and long sides in the second direction DR2. The corners where the short sides in the first direction DR1 and the long sides in the second direction DR2 meet may be rounded to have a predetermined curvature, but the present disclosure is not limited thereto. Alternatively, these corners may be formed at right angles. The planar shape of the display device 10 is not limited to a rectangle and may be formed in various other shapes similar to other polygons, circles, or ellipses. The other polygons may include, for example, triangles, pentagons, hexagons, octagons, or decagons, but the present disclosure is not limited thereto.

The display device 10 may include a display panel 100, a driver chip DIC, and a driver substrate PCB.

The display panel 100 may include a main area MA, a sub-area SA, and a bending area BA. The bending area BA may be disposed between the main area MA and the sub-area SA in the second direction DR2. The main area MA may be disposed on one side of the bending area BA in the second direction DR2. The sub-area SA may be disposed on the other side of the bending area BA in the second direction DR2.

The main area MA may include a display area DA that includes pixels for displaying an image, and a non-display area NDA that is disposed around the display area DA. The pixels may include a red pixel, a green pixel, and a blue pixel, and may further include a white pixel according to an embodiment of the present disclosure. The display area DA may emit light from a plurality of light-emitting areas or a plurality of aperture areas. For example, the display panel 100 may include pixel circuits that include switching elements, a pixel-defining film that defines the light-emitting areas or aperture areas, and self-light-emitting elements. The pixel-defining film may include an organic light-shielding material or inorganic light-shielding material including a black pigment and/or a black dye according to an embodiment of the present disclosure.

The self-light-emitting elements may include at least one of, for example, organic light-emitting diodes (OLEDs) with organic light-emitting layers, quantum dot light-emitting diodes (LEDs) with quantum dot light-emitting layers, inorganic LEDs with inorganic semiconductors, micro-LEDs, or nano-LEDs but the present disclosure is not limited thereto.

The main area MA may generally have a shape similar to the planar exterior of the display panel 100. The main area MA may be a flat area located on one plane, but the present disclosure is not limited thereto. Alternatively, at least some of the edges of the main area MA may be curved in a third direction DR3 or bent vertically.

When at least some of the edges of the main area MA are curved in the third direction DR3 or bent vertically, the display area DA may also be disposed on these curved or bent edges, but the present disclosure is not limited thereto. In this case, these curved or bent edges of the display area DA may constitute bending display areas, and may display image. Alternatively, the curved or bent edges may become the non-display area NDA that does not display an image, or a mixed area where both the display area DA and the non-display area NDA coexist.

The bending area BA may be connected to the other side of the main area MA in the second direction DR2. For example, the bending area BA may be connected through the lower short side of the main area MA. The width, in the first direction DR1, of the bending area BA may be smaller than the width, in the first direction DR1, of the main area MA adjacent to the bending area BA. The connection part between the main area MA and the bending area BA may have an L-shaped cut shape.

The bending area BA may be the area where the display panel 100 bends. In the bending area BA, the display panel 100 may bend with curvature in a downward direction along its thickness. For example, in the bending area BA, the display panel 100 may bend to the other side in the third direction DR3.

The bending area BA may have a constant curvature radius, but the present disclosure is not limited thereto. For example, the main area MA and the sub-area SA may each have one flat surface, and may not be folded or bent, while the bending area BA may have a flat surface located on a plane the same as that of the surfaces of the main area MA and the sub-area SA in an unfolded state, but it may be folded or bent to have a curved surface with the constant curvature radius. Alternatively, the bending area BA may have different curvature radii in different sections. As the display panel 100 bends in the bending area BA, its surfaces may be reversed. For example, the display panel 100 may bend in the opposite direction to a first surface 100a which is the display surface of the display panel 100. Accordingly, a second surface 100b of the main area MA and a second surface 100b of the sub-area SA, which are opposite to the display surface, may face each other in the third direction DR3.

The main area MA may be disposed on one side of the bending area BA and extend from the bending area BA in the second direction DR2. The sub-area SA may be disposed on the other side of the bending area BA in the second direction DR2. The sub-area SA may extend from the bending area BA. The width, in the first direction DR1, of the sub-area SA may be greater than the width, in the first direction DR1, of the bending area BA. The connection part between the sub-area SA and the bending area BA may have an L-shaped cut shape. However, the present disclosure is not limited thereto. For example, the width, in the first direction DR1, of the sub-area SA may be the same as the width, in the first direction DR1, of the bending area BA.

In an embodiment of the present disclosure, the size of the sub-area SA may be smaller than the size of the main area MA of the display panel 100. For example, as illustrated in FIG. 3, in the bent state of the display panel 100, the sub-area SA may completely overlap the main area MA. In the bent state of the display panel 100, the outer edges of the sub-area SA may be surrounded by the outer edges of the main area MA in a plan view. The outer edges of the sub-area SA may be positioned inwardly from the outer edges of the main area MA in a plan view.

As illustrated in FIG. 3, in the bent state of the display panel 100, the sub-area SA may overlap with the main area MA in the thickness direction of the display panel 100, i.e., in the third direction DR3. The sub-area SA may be disposed below the main area MA in the third direction DR3.

The driver chip DIC may be disposed on the sub-area SA of the display panel 100. In an embodiment of the present disclosure, the driver chip DIC may be disposed on the first surface 100a of the display panel 100 in the sub-area SA. In an embodiment of the present disclosure, as illustrated, the driver chip DIC may be directly mounted on the display panel 100 using a chip-on-glass (COG) or chip-on-plastic (COP) method. In an embodiment of the present disclosure, the driver chip DIC may be mounted on a flexible film using a chip-on-film (COF) method.

The driver chip DIC may generate and output data voltages, power supply voltages, scan timing signals, and the like. The driver chip DIC may include an integrated circuit (IC) for driving the display panel 100. The integrated circuit may include a display integrated circuit (IC) and/or a touch unit IC, but the present disclosure is not limited thereto. The display IC and the touch unit IC may be provided as separate chips or may be integrated into a single chip.

The driver substrate PCB may be disposed on one end of the sub-area SA of the display panel 100, and may be configured to transfer signals or powers to or from the display panel 100. A pad portion may be disposed at one end of the sub-area SA of the display panel 100. The pad portion may include a plurality of display signal wiring pads and touch signal wiring pads. The driver substrate PCB may be connected to the pad portion at one end of the sub-area SA of the display panel 100. The driver substrate PCB may be attached to the pad portion using a conductive adhesive member such as an anisotropic conductive film or an anisotropic conductive adhesive. The driver substrate PCB may be a flexible film such as a flexible printed circuit board (FPCB) or a COF.

In the bent state of the display panel 100, the driver chip DIC, and the driver substrate PCB may be positioned on the opposite side of the main area MA of the display panel 100 with the sub-area SA of the display panel 100 disposed therebetween. That is, the driver chip DIC and the driver substrate PCB may be disposed on the first surface 100a of the sub-area SA and may become farther from the main area MA in the third direction DR3 as the display panel 100 bends.

In an embodiment of the present disclosure, the size of the driver substrate PCB may be smaller than the size of the main area MA of the display panel 100. For example, as illustrated in FIG. 3, in the bent state of the display panel 100, the driver substrate PCB may be completely overlapped by the main area MA. In the bent state of the display panel 100, the outer edges of the driver substrate PCB may be surrounded by the outer edges of the main area MA in a plan view. The outer edges of the driver substrate PCB may be positioned inwardly from the outer edges of the main area MA in a plan view.

The present disclosure is not limited to the feature described above. For example, some of the outer edges of the driver substrate PCB may coincide with or be positioned outside some of the outer edges of the display panel 100. In this case, the arc radius of the driver substrate PCB may be equal to or greater than the arc radius of the display panel 100.

The planar shape of the driver substrate PCB may be approximately similar to the planar shape of the display panel 100. For example, if the planar shape of the display panel 100 is circular, at least part of the driver substrate PCB may also be circular. However, the present disclosure is not limited thereto, and the shape of the driver substrate PCB may vary.

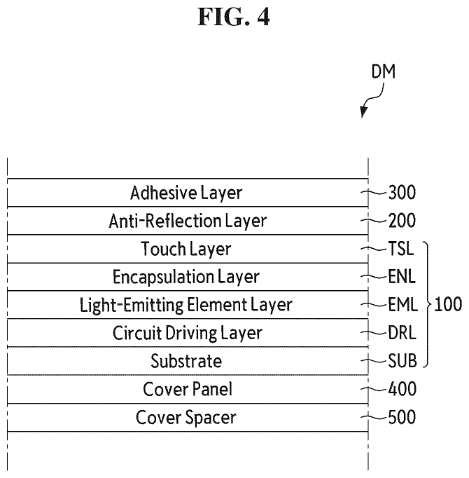

FIG. 4 is a schematic cross-sectional view illustrating a stack structure of a display module according to an embodiment of the present disclosure.

Referring to FIG. 4, a display module DM may include a display panel 100, an anti-reflection layer 200, an adhesive layer 300, a cover panel 400, and a cover spacer 500. The display panel 100 may include a substrate SUB, and a circuit driving layer DRL, a light-emitting element layer EML, an encapsulation layer ENL, and a touch layer TSL sequentially disposed on the substrate SUB.

The substrate SUB may support the components disposed on its upper surface. The substrate SUB may include a transparent material. For example, the substrate SUB may include a transparent insulating material such as glass or quartz. The substrate SUB may be a rigid substrate, but the present disclosure is not limited thereto. Alternatively, the substrate SUB may include plastic such as polyimide and may have flexible properties such as bendability, foldability, or rollability.

The circuit driving layer DRL may be disposed on a first surface of the substrate SUB, for example, on the upper surface of the substrate SUB. The circuit driving layer DRL may include an insulating layer, a semiconductor pattern, a conductive pattern, a signal line, and the like. The circuit driving layer DRL may include circuits for driving the light-emitting element layer EML of each pixel. The circuit driving layer DRL may include a plurality of thin-film transistors (TFTs) and a plurality of capacitors.

The light-emitting element layer EML may be disposed on the circuit driving layer DRL. The light-emitting element layer EML may include an organic light-emitting layer. Alternatively, the light-emitting element layer EML may include, for example, inorganic light-emitting material, organic-inorganic light-emitting material, quantum dot, quantum rod, micro LED, or nano LED. The light-emitting element layer EML may emit light with various brightness levels according to driving signals transmitted from the circuit driving layer DRL.

The encapsulation layer ENL may be disposed on the light-emitting element layer EML. The encapsulation layer ENL may include an inorganic film or a stack of inorganic and organic films. Alternatively, the encapsulation layer ENL may include glass or an encapsulation film. The encapsulation layer ENL may seal the light-emitting element layer EML. For example, the encapsulation layer ENL may protect the light-emitting element layer EML from moisture, oxygen, and foreign matter such as dust particles.

The touch layer TSL may be disposed on the encapsulation layer ENL. The touch layer TSL, which is a layer that senses touch input, may function as a touch member. The touch layer TSL may include a plurality of sensing areas and sensing electrodes, and may be driven in a mutual capacitance method in which a voltage charged in mutual capacitance is sensed through sensing electrodes after applying driving signals to driving electrodes.

The anti-reflection layer 200 may be disposed on the display panel 100. The anti-reflection layer 200 may function to reduce external light reflection, and may enhance color purity of a light emitted from the display device 10. The anti-reflection layer 200 may be attached in the form of a polarizing film. In this case, the anti-reflection layer 200 may polarize light passing therethrough. The anti-reflection layer 200 according to an embodiment of the present disclosure may include a retarder and a polarizer. However, the present disclosure is not limited to this. Alternatively, the anti-reflection layer 200 may also be stacked in the form of a color filter layer. In this case, the anti-reflection layer 200 may include color filters that selectively transmit light of specific wavelengths therethrough.

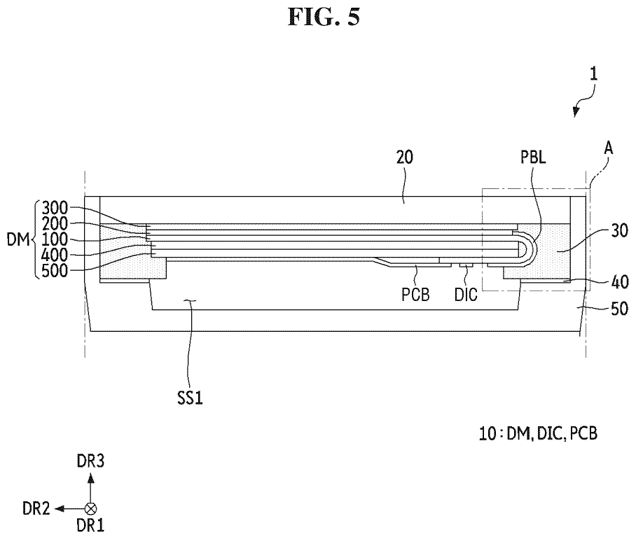

The adhesive layer 300 may be disposed on the anti-reflection layer 200. The adhesive layer 300 may adhere a cover window (20 in FIG. 5) to the display panel 100 or the anti-reflection layer 200. In an embodiment of the present disclosure, the adhesive layer 300 may be an optically clear adhesive (OCA) film or a pressure-sensitive adhesive (PSA) film. In an embodiment of the present disclosure, the adhesive layer 300 may include a heat curable resin or a photocurable resin. However, the adhesive layer 300 may not be included in the display device 10 and may instead be attached to, and provided together with, the cover window 20.

The cover panel 400 may be disposed on a second surface of the substrate SUB, for example, on the lower surface of the substrate SUB. The cover panel 400 may include at least one functional layer and may thereby perform functions such as heat dissipation, electromagnetic shielding, cushioning, strength reinforcement, support, and/or adhesion. For example, the functional layer of the cover panel 400 may be a sheet layer composed of a sheet, a film layer, a thin film layer, a coating layer, a panel, or a plate. A single functional layer may be formed as a single layer, but may also be formed as a stack of multiple thin films or coating layers. The functional layer may be, for example, a support substrate, a heat dissipation layer, an electromagnetic shielding layer, a shock absorption layer, a bonding layer, and the like.

The cover spacer 500 may be disposed on the cover panel 400, for example, on the lower surface of the cover panel 400. The cover spacer 500 may prevent or mitigate the bending of the display panel 100 due to external force. The cover spacer 500 may keep the display panel 100 relatively flat even when an external force is applied.

The cover spacer 500 may include a material that is rigid or semi-rigid. For example, the cover spacer 500 may include a metal material such as, for example, stainless steel (SUS) or aluminum (Al), or a polymer such as, for example, polymethylmethacrylate (PMMA), polycarbonate (PC), polyvinyl alcohol (PVA), acrylonitrile-butadiene-styrene (ABS), or polyethylene terephthalate (PET).

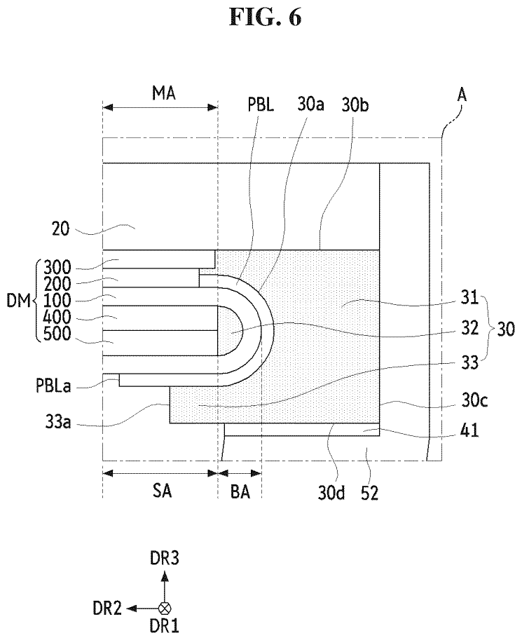

FIG. 5 is a schematic cross-sectional view illustrating an electronic device according to an embodiment of the present disclosure. FIG. 6 is an enlarged cross-sectional view of area A of FIG. 5.

The electronic device 1 may include the display device 10, the cover window 20, an outer structure 30, a coupling member 40, and a frame 50.

As described with reference to FIGS. 2 and 3, the display device 10 may further include the driver chip DIC and the driver substrate PCB. As described with reference to FIG. 4, the display device 10 may include the display panel 100, the anti-reflection layer 200, the adhesive layer 300, the cover panel 400, and the cover spacer 500. The configuration of the display device 10 is as already described, and thus, a detailed description thereof will be omitted.

The cover spacer 500 may reinforce the height difference formed between the sub-area SA of the display panel 100 and the cover panel 400, and between the driver substrate PCB and the cover panel 400. For example, as the cover spacer 500 is disposed between the sub-area SA of the display panel 100 and the cover panel 400, and between the driver substrate PCB and the cover panel 400 in the third direction DR3, the cover spacer 500 may maintain the display panel 100 and the driver substrate PCB in a flat state. In an embodiment of the present disclosure, the display panel 100 and the driver substrate PCB may be attached to the lower part of the cover spacer 500 via separate adhesive members. Accordingly, the display panel 100 and the driver substrate PCB may maintain a fixed state.

The display module DM may further include a bending protection layer PBL. The bending protection layer PBL may be disposed on part of the display panel 100. In an embodiment of the present disclosure, the bending protection layer PBL may be disposed on the bending area BA of the display panel 100, but the present disclosure is not limited thereto. For example, the bending protection layer PBL may be disposed on one surface of the display panel 100. Alternatively, the bending protection layer PBL may also be disposed on areas other than the bending area BA.

The bending protection layer PBL may be formed of a polymer compound such as, for example, polyimide, acrylate, or epoxy. The bending protection layer PBL can minimize the formation of cracks due to stress applied to the display panel 100 during bending and can prevent the propagation of such cracks. Accordingly, the durability of the display module DM may be enhanced.

The cover window 20 may be attached to the display device 10 through the adhesive layer 300 of the display module DM. The cover window 20 may be made of a transparent insulating material, and may be glass, quartz or plastic. For example, the cover window 20 may be ultra-thin glass (UTG) having a thickness of about 0.1 mm or less. Alternatively, the cover window 20 may be a transparent polyimide film. The size of the cover window 20 may be greater than the size of the display device 10. Therefore, the cover window 20 may protrude outwardly beyond the display device 10.

The outer structure 30 may be disposed between the cover window 20 and the frame 50 in the third direction DR3. The outer structure 30 may surround the display device 10 in a plan view. As illustrated in FIG. 5, the outer structure 30 may surround the display device 10 in horizontal directions defined by the first and second directions DR1 and DR2. For example, the outer structure 30 may surround the driver substrate PCB and the bending protection layer PBL. The outer structure 30 may be surrounded by the sidewalls of the frame 50 in a plan view. The outer structure 30 may be surrounded by the sidewalls of the frame 50 in the horizontal directions defined by the first and second directions DR1 and DR2.

As illustrated in FIG. 5, the outer structure 30 may be disposed between the display device 10, the cover window 20, the coupling member 40, and the frame 50. The outer structure 30 may connect the display device 10, the cover window 20, the coupling member 40, and the frame 50. As described with reference to FIG. 5, the display device 10 may include the display module DM, the driver chip DIC, and the driver substrate PCB.

The coupling member 40 may be an adhesive tape with an adhesive material applied on both sides and may have waterproof or dustproof functions. The coupling member 40 may be disposed on the upper surface of the frame 50. The coupling member 40 may be disposed between the frame 50 and the outer structure 30 in the third direction DR3 to couple the frame 50 and the outer structure 30.

The frame 50 may function as a bracket for securing the cover window 20. The display device 10 may be disposed between the frame 50 and the cover window 20. For example, the frame 50 may be coupled to the cover window 20 to provide a predetermined inner space. The display device 10 may be accommodated in the inner space. In other words, the cover window 20 may couple with the frame 50 to fix in place the display device 10. The upper surface of the frame 50 may face the lower surface of the display device 10. The upper surface of the frame 50 may be spaced apart from the lower surface of the display device 10. A storage space SS1 may be formed between the upper surface of the frame 50 and the lower surface of the display device 10. The storage space SS1 may provide space for housing peripheral circuits of the electronic device 1, such as a host driving system, memory, and battery.

As illustrated in FIG. 6, the outer structure 30 may include a first portion 31, a second portion 32 and a third portion 33. The third portion 33 overlaps the main area MA in the third direction DR3. The second portion 32 is separated from the first and second portions 31 and 33 by the display panel 100 and the bending protection layer PBL. The outer structure 30 may include inner surface 30a, upper surface 30b, outer surface 30c and lower surface 30d. The coupling member 41 may be disposed on the upper surface of the frame 52. The lower side surface PBLa of the bending protection layer PBL is disposed under the display panel 100.

The outer structure 30 may be fabricated by injecting a paste between the display device 10 and the frame 50 and then curing the paste. The area where the outer structure 30 is applied may include the bending protection layer PBL disposed in the bending area BA of the display panel 100 and the cover panel 400 disposed on one surface of the display panel 100. If the bending protection layer PBL or the cover panel 400 contains an amine compound, the amine compound may inhibit the curing of the epoxy material in the paste, for example, a cationic epoxy material. Amines are bases that react with acids to form salts. For example, the acid generated by the photodecomposition of the photopolymerization initiator in the paste may be trapped by the amine in the bending protection layer PBL or the cover panel 400, preventing the paste from being used for polymerization initiation and resulting in an uncured paste.

A filler composition according to an embodiment of the present disclosure, capable of preventing uncured areas caused by the amine in the bending protection layer PBL or the cover panel 400, will hereinafter be disclosed. The filler composition according to an embodiment of the present disclosure may be applied to a display device including the bending protection layer PBL.

The filler composition according to an embodiment of the present disclosure may include at least one selected from among a cationic polymerizable compound, a cationic photopolymerization initiator, a phosphoric compound, or a carboxylic acid compound.

The cationic polymerizable compound may include a cyclic compound having an epoxy group and an aromatic compound having an epoxy group.

The aromatic compound having an epoxy group may include bisphenol A-type epoxy resin and bisphenol F-type epoxy resin. Bisphenol A has two phenol groups connected by a propane bridge. Bisphenol A-type epoxy resin refers to epoxy resins that contain bisphenol A. Here, the bisphenol F represents two phenol groups connected by a fluorene bridge. A fluorene molecule, which has chemical formula (C₆H₄)₂CH₂, consists of a central methylene group (—CH₂—) sandwiched between two benzene rings, essentially forming a “V” shape with the molecule being almost planar. Bisphenol F-type epoxy resin refers to epoxy resins that contain bisphenol F. For example, the bisphenol A-type epoxy resin and the bisphenol F-type epoxy resin may be any one of the compounds represented by the following chemical formulas.

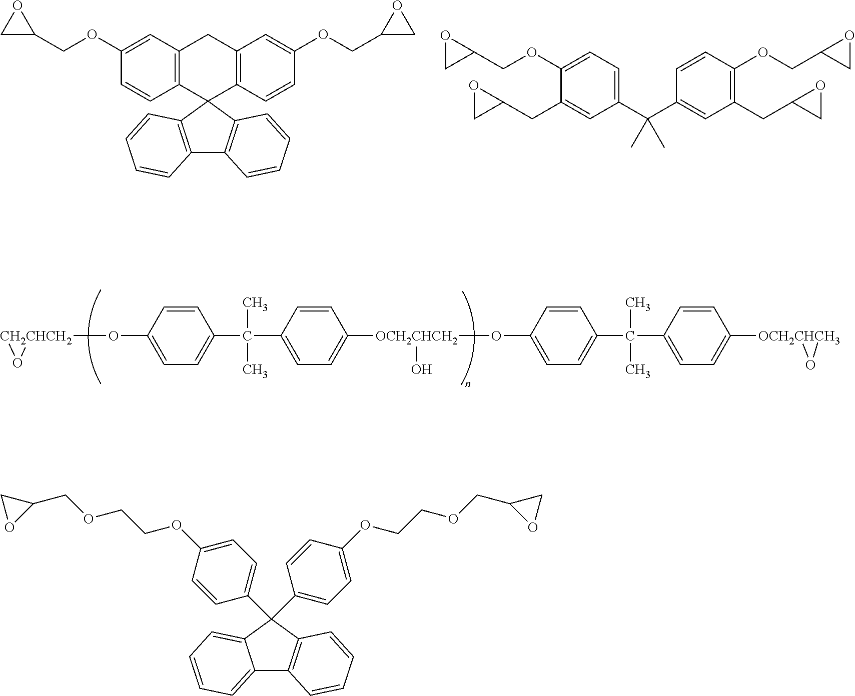

The mass ratio of the bisphenol A-type epoxy resin to the bisphenol F-type epoxy resin may be from about 0.2 to about 5.

The cyclic compound having an epoxy group may be, for example, any one of the compounds represented by the following chemical formulas. The compound 1,3-bis(2,3-epoxypropoxy)-2,2-bis[(2,3-epoxypropoxy)methyl]propane may be used instead of a cyclic compound having an epoxy group included in the cationic polymerizable compound.

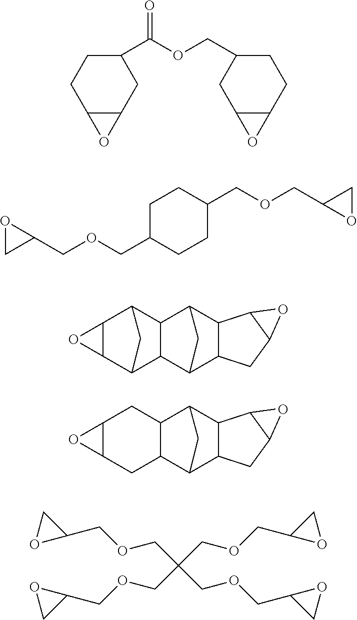

The cationic photopolymerization initiator may function to initiate the photopolymerization of the cationic polymerizable compound. The cationic photopolymerization initiator may include at least one selected from among a sulfonium salt, an iodonium salt, an onium salt other than the sulfonium salt and the iodonium salt, or a nonionic acid initiator, such as, for example, 2-isopropylthioxanthone, camphorquinone, or ethyl 4-dimethylaminobenzoate. For example, the cationic photopolymerization initiator may be any one of the compounds represented by the following chemical formulas.

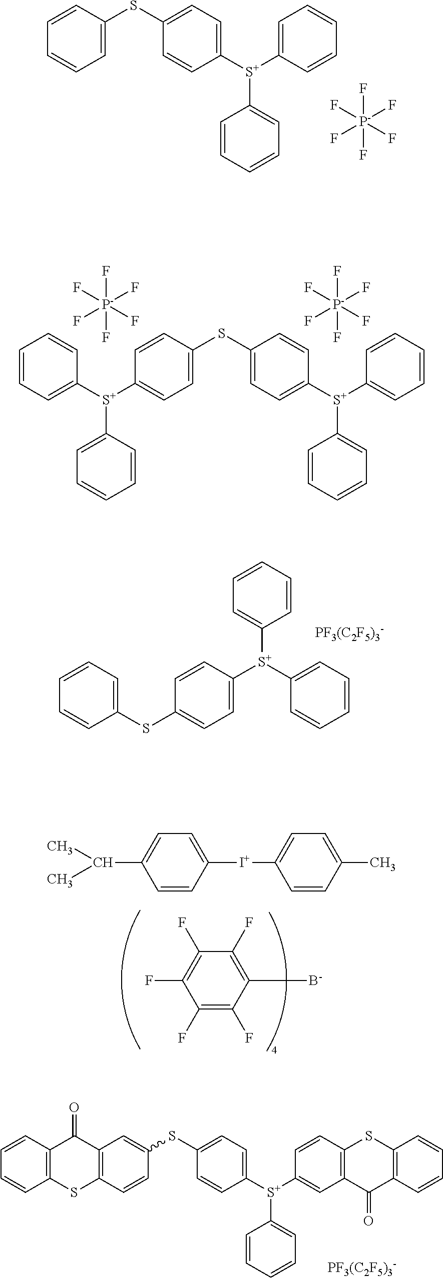

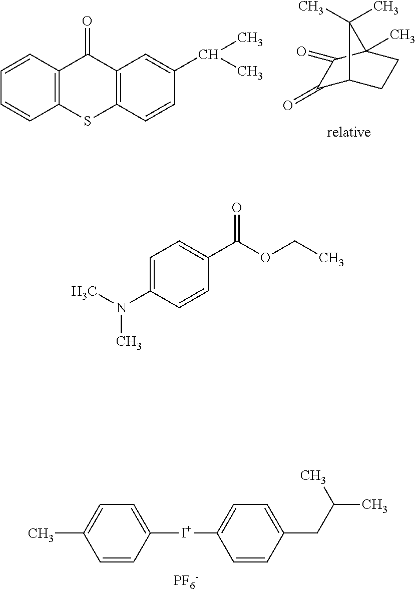

In an embodiment of the present disclosure, the cationic photopolymerization initiator may include an onium salt other than the sulfonium salt and the iodonium salt, such as, for example, a diazonium salt, a chloronium salt, or a bromonium salt. Alternatively, in an embodiment of the present disclosure, the cationic photopolymerization initiator may include an onium salt including both the sulfonium salt and the iodonium salt.

The cationic photopolymerization initiator may be included in an amount of about 0.05 to about 50 parts by mass per 100 parts by mass of the cationic polymerizable compound.

The phosphoric compound or carboxylic acid compound may neutralize the basic amine included in the bending protection layer PBL or the cover panel 400 to prevent the inhibition of a photopolymerization reaction. For example, as shown in the following reaction equation, when the cationic polymerizable compound is polymerized by light, a low molecular weight acid HA of the phosphoric compound combines with the basic amine to neutralize the basic amine. For example, the basic amine R₁—N—(R₂)(R₃), in which R₁, R₂ and R₃, are each independently a substituted or unsubstituted hydrocarbon group, may react with the low molecular weight acid HA to form the neutral salt R₁—NH⁺—(R₂)(R₃)A⁻. Accordingly, the amine may be prevented from interfering with the photopolymerization reaction of the paste, allowing the photopolymerization reaction of the cationic polymerizable compound to proceed smoothly. For example, the cationic photopolymerization initiator may be exposed to light (hv) to form an acid HX. The acid HX may catalyze the polymerization of the compound having an epoxy group to form a polymer.

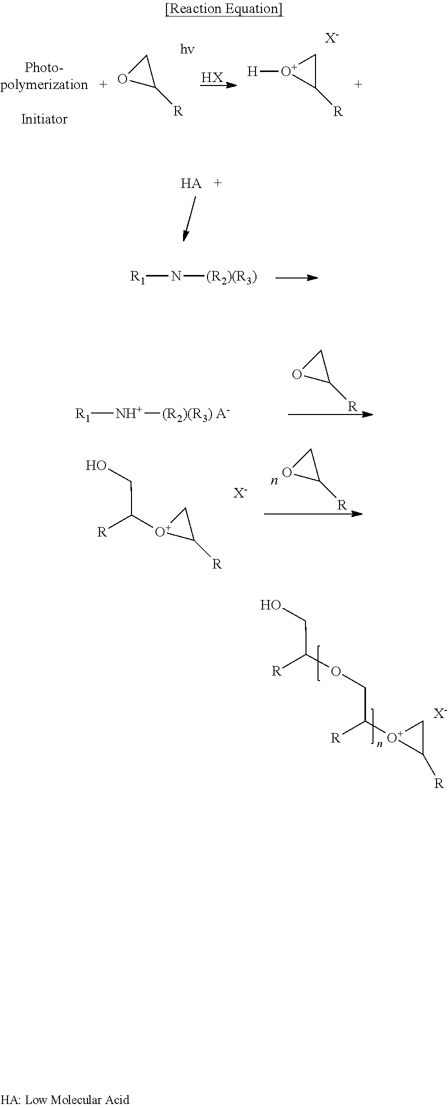

The phosphoric compound may include at least one selected from among the compounds represented by Chemical Formulas 1 through 4 below.

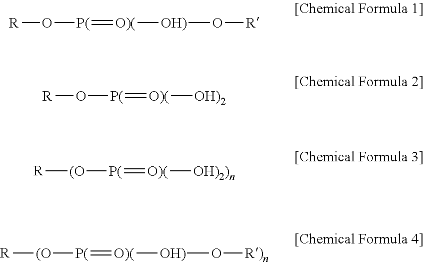

In the above chemical formulas, R and R′ are each independently a substituted or unsubstituted hydrocarbon group, and n is from 2 to 10.

The phosphoric compound may include a phosphoric ester, which may include the compounds represented by the following chemical formulas.

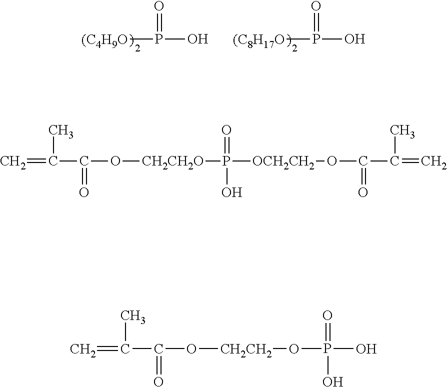

To neutralize the aforementioned basic amine and prevent the inhibition of the photopolymerization reaction, the molecule's diffusibility for enhanced neutralization speed is required. To this end, the molecular weight of the phosphoric ester in the phosphoric compound may be about 400 or less.

The carboxylic acid compound may include at least one selected from among the compounds represented by Chemical Formulas 5 and 6.

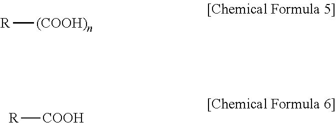

In the above chemical formulas, R is each independently a substituted or unsubstituted hydrocarbon group, and n is from 2 to 10.

For example, the carboxylic acid compound may include the compounds represented by the following chemical formulas.

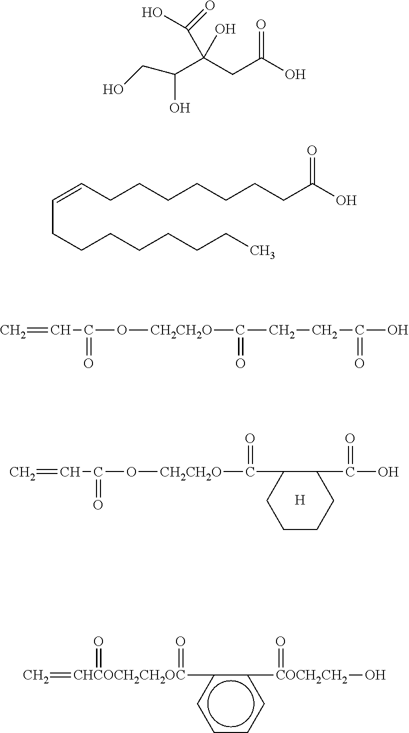

The phosphoric compound or carboxylic acid compound may be included in an amount of about 0.1 to about 5 parts by mass per 100 parts by mass of the cationic polymerizable compound. In this case, significant changes in the physical properties of the paste may be prevented, and the stability of the liquid during storage is ensured.

The filler composition according to an embodiment of the present disclosure may include additives. For example, the additives may include at least one selected from among, for example, a photoinitiator, a silane coupling agent, a surface tension modifier, a plasticizer, or a thixotropic agent, but the present disclosure is not limited thereto.

The viscosity of the filler composition according to an embodiment of the present disclosure may be from about 1,000 cps to about 20,000 cps. If the viscosity of the filler composition according to an embodiment of the present disclosure is about 1,000 cps or more, it can prevent the paste from flowing, ensuring workability. Additionally, if the viscosity of the filler composition according to an embodiment of the present disclosure is about 20,000 cps or less, it may prevent an increase in injection time or incomplete injection of the paste.

As described above, the filler composition according to an embodiment of the present disclosure includes at least one selected from among the cationic polymerizable compound, the cationic photopolymerization initiator, the phosphoric compound, or the carboxylic acid compound, thereby preventing photo-curing inhibition caused by the amine in the protection layer PBL or cover panel 400. Thus, the filler composition according to an embodiment of the present disclosure may prevent the uncuring of the outer structure 30 formed by the filler composition. For example, the filler composition according to an embodiment of the present disclosure may prevent the uncuring of the outer structure 30 at the interface with the bending protection layer PBL.

A method for manufacturing a display device using the aforementioned filler composition will hereinafter be described.

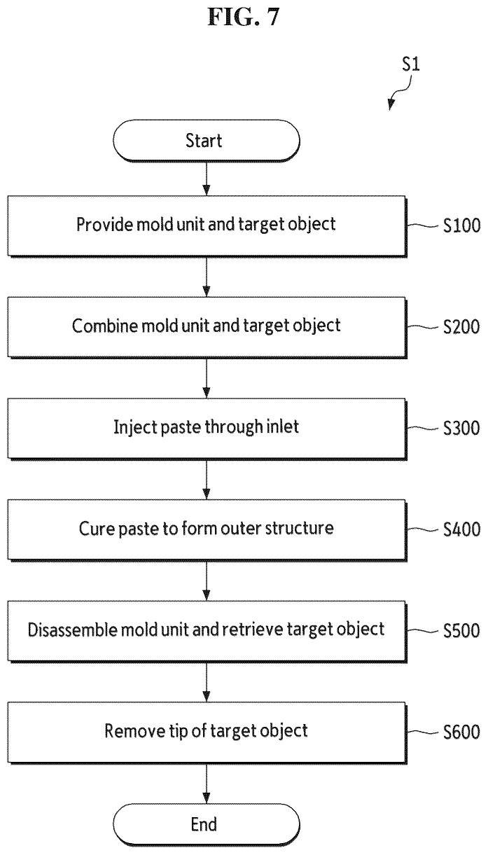

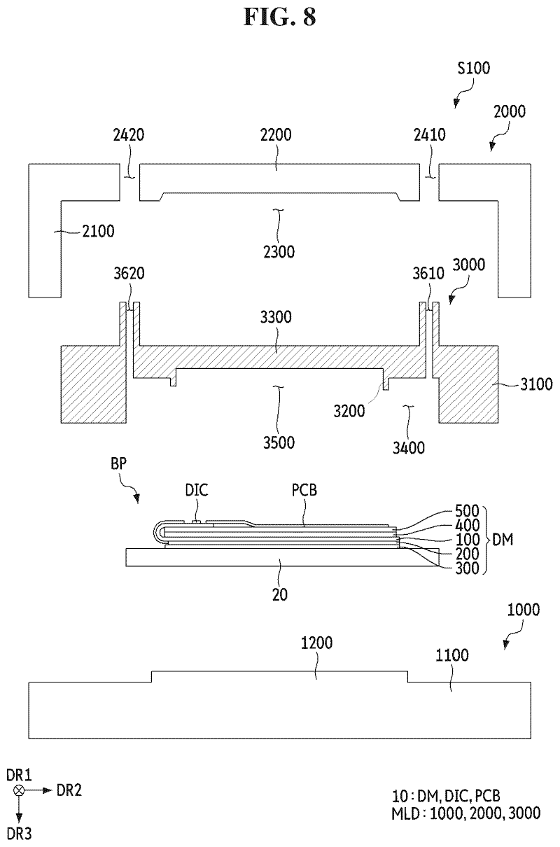

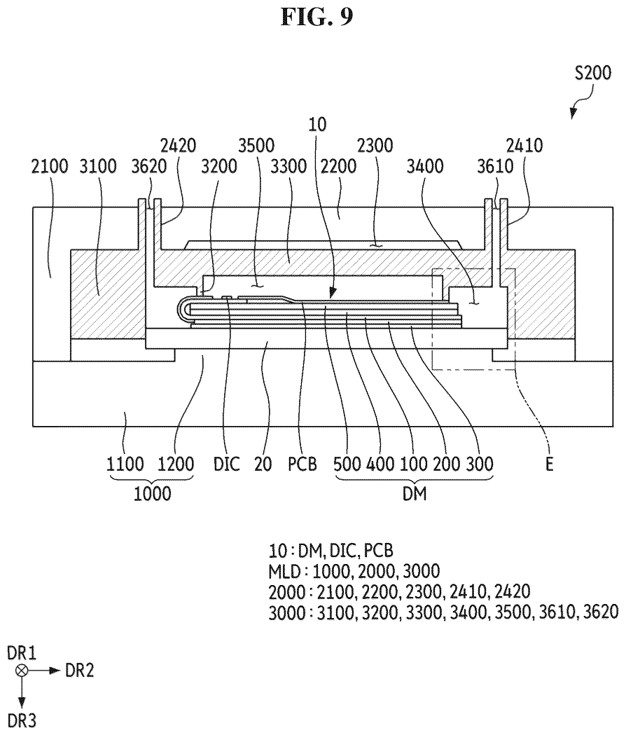

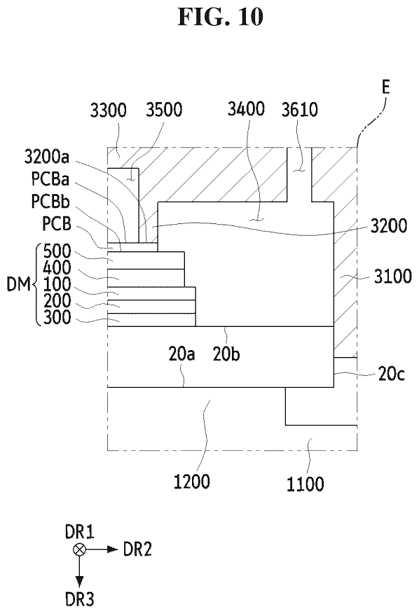

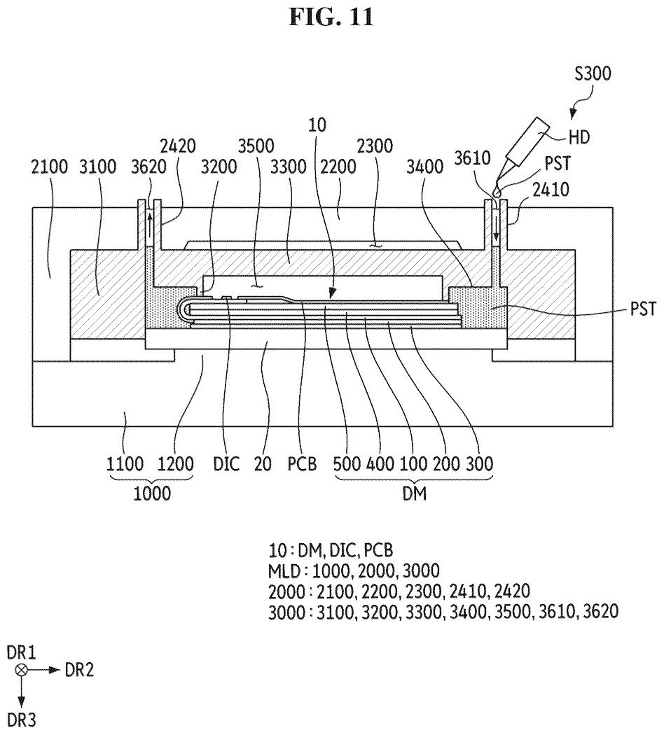

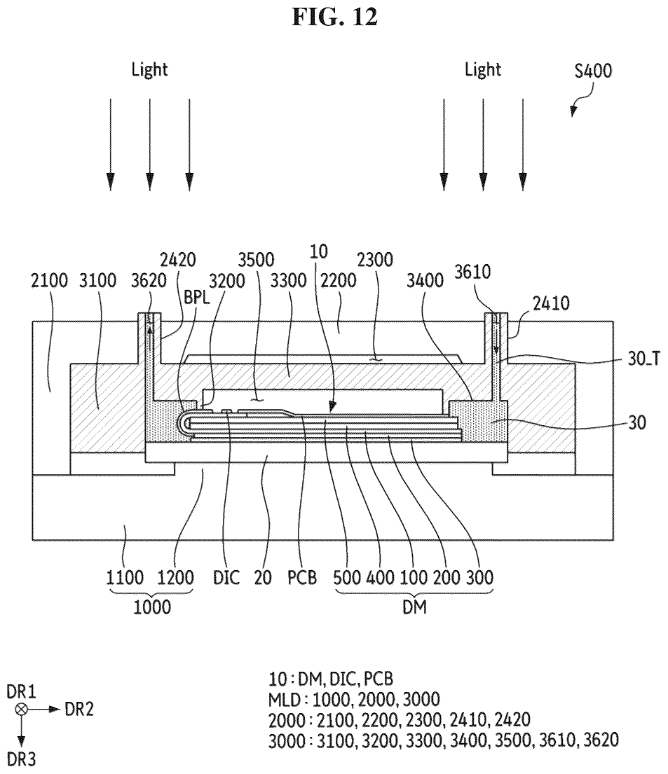

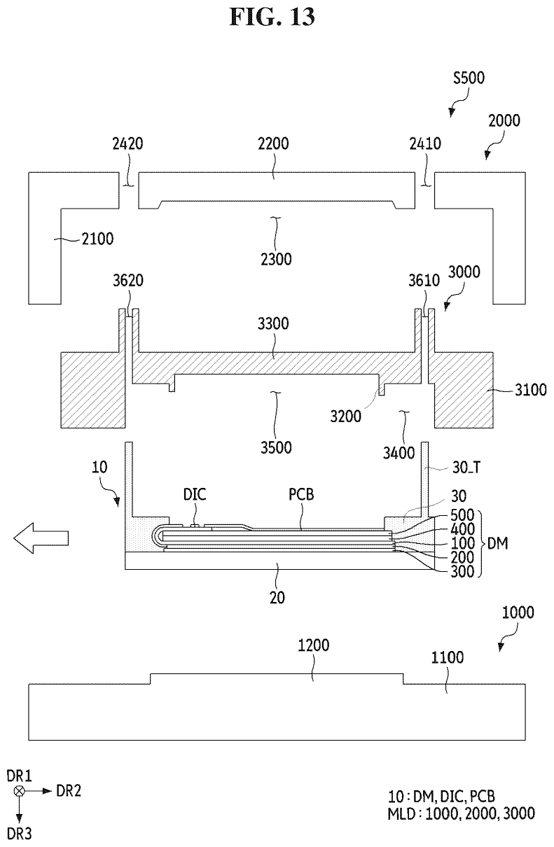

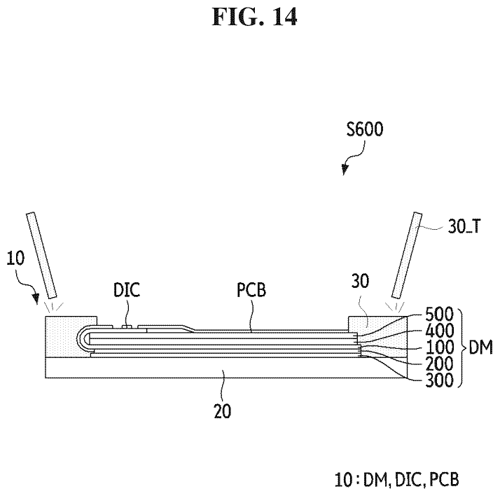

FIG. 7 is a flowchart illustrating a method for manufacturing an electronic device according to an embodiment of the present disclosure. FIG. 8 is a cross-sectional view illustrating step S100 of FIG. 7. FIG. 9 is a cross-sectional view illustrating step S200 of FIG. 7. FIG. 10 is an enlarged cross-sectional view of area E of FIG. 9. FIG. 11 is a cross-sectional view illustrating step S300 of FIG. 7. FIG. 12 is a cross-sectional view illustrating step S400 of FIG. 7. FIG. 13 is a cross-sectional view illustrating step S500 of FIG. 7. FIG. 14 is a cross-sectional view illustrating step S600 of FIG. 7.

Referring to FIGS. 7 through 14, a method S1 for manufacturing a display device according to an embodiment of the present disclosure may include the steps of: providing a mold unit and a target object (S100); combining the mold unit and the target object (S200); injecting a paste through an inlet (S300); curing the paste to form an outer structure (S400); disassembling the mold unit and retrieving the target object (S500); and removing the tip of the target object (S600).

As illustrated in FIG. 8, in step S100, a mold unit MLD and a target object may be provided.

The target object may be the display device 10 of the electronic device 1 described above with reference to FIGS. 2 through 6. The display device 10, which is the target object of the method S1, may be in a state where the cover window 20 is combined. In FIG. 8, BP represents the combination of cover window 20 and the display device 10, and the display device 10 includes the display module DM, the driver chip DIC, and the driver substrate PCB.

The mold unit MLD may be an apparatus for manufacturing a display device to form the outer structure 30. The mold unit MLD may include a lower mold 1000, an upper mold 2000, and an inner mold 3000.

The lower mold 1000 may be disposed below the display device 10, which is the target object. The lower mold 1000 may include a base 1100 and a seating portion 1200.

The base 1100 may form the body of the lower mold 1000. The area of the base 1100 may be larger than the area of the target object.

The seating portion 1200 may be disposed on the base 1100. The seating portion 1200 may be part of the lower mold 1000 protruding from the base 1100 in the third direction DR3. The seating portion 1200 and the base 1100 may physically form a single structure, but the present disclosure is not limited thereto. The seating portion 1200 is illustrated as having a smaller size than the cover window 20, but the present disclosure is not limited thereto. The size of the seating portion 1200 may be the same as or larger than the size of the cover window 20.

The upper mold 2000 may be disposed above the lower mold 1000. The upper mold 2000 may be disposed above the display device 10, which is the target object. The upper mold 2000 may include a first outer wall 2100, a first top plate 2200, a first receiving portion 2300, a first coupling hole 2410, and a second coupling hole 2420.

The first outer wall 2100 and the first top plate 2200 may form the body of the upper mold 2000. The outer shape of the upper mold 2000 defined by the first outer wall 2100 and the first top plate 2200 may approximately correspond to the outer shape of the base 1100 of the lower mold 1000, but the present disclosure is not limited thereto.

The first receiving portion 2300 may be a space formed by the first outer wall 2100 and the first top plate 2200. The first receiving portion 2300 may provide space for accommodating the inner mold 3000.

The first and second coupling holes 2410 and 2420 may be disposed on the first top plate 2200. The first and second coupling holes 2410 and 2420 may be through holes penetrating the upper and lower surfaces of the first top plate 2200. The first coupling hole 2410 may be a hole for coupling an inlet 3610 of the inner mold 3000, and the second coupling hole 2420 may be a hole for coupling an outlet 3620 of the inner mold 3000.

In an embodiment of the present disclosure, the lower mold 1000 and the upper mold 2000 may include at least one of, for example, stainless steel (SUS) or aluminum (Al), but the present disclosure is not limited thereto.

The inner mold 3000 may be disposed between the lower mold 1000 and the upper mold 2000. The inner mold 3000 may be an additional mold disposed between the lower mold 1000 and the upper mold 2000 for accurately sealing the target object. The inner mold 3000 may include a second outer wall 3100, an inner wall 3200, a second top plate 3300, a cavity 3400, a second receiving portion 3500, the inlet 3610, and the outlet 3620.

The second outer wall 3100 and the second top plate 3300 may form the body of the inner mold 3000. The outer shape of the inner mold 3000, defined by the second outer wall 3100 and the second top plate 3300, may approximately correspond to the outer shape of the first receiving portion 2300 of the upper mold 2000, but the present disclosure is not limited thereto.

The inner wall 3200 may be located inside the second outer wall 3100. The inner wall 3200 may be surrounded by the second outer wall 3100. The inner wall 3200 may be a partition wall for isolating the cavity 3400 and the second receiving portion 3500. The inner wall 3200 may extend approximately in the third direction DR3, but the present disclosure is not limited thereto. Alternatively, the inner wall 3200 may extend diagonally.

The cavity 3400 may be located between the second outer wall 3100 and the inner wall 3200. The cavity 3400 may be a space formed by the second outer wall 3100, the inner wall 3200, and the second top plate 3300. The cavity 3400 may provide space for forming the outer structure 30.

The second receiving portion 3500 may be located inside the inner wall 3200. The second receiving portion 3500 may be a space formed by being surrounded by the inner wall 3200 and the second top plate 3300. In the combined state of the mold unit MLD, the second receiving portion 3500 may be isolated from the cavity 3400 by the inner wall 3200. Accordingly, a paste PST may be prevented from leaking into the second receiving portion 3500.

The inlet 3610 and the outlet 3620 may be disposed on the second top plate 3300. The inlet 3610 and the outlet 3620 may be passages penetrating the upper and lower surfaces of the second top plate 3300. The inlet 3610 and the outlet 3620 may protrude further than the second top plate 3300 in the third direction DR3. The protruding parts of the inlet 3610 and the outlet 3620 may be respectively coupled to the first coupling hole 2410 and the second coupling hole 2420 of the upper mold 2000.

The inlet 3610 may be a passage through which the paste PST is injected. The outlet 3620 may be a passage through which excess paste PST is discharged. The inlet 3610 and the outlet 3620 may be passages connecting the cavity 3400 and the exterior, allowing the paste PST to be injected into or discharged from the cavity 3400.

In an embodiment of the present disclosure, the inner mold 3000 may include a material with appropriate strength and elasticity to maintain its shape under normal conditions but change shape slightly when the mold unit MLD is combined. For example, the inner mold 3000 may include silicone, but the present disclosure is not limited thereto. Accordingly, even if there is a step difference in the part where the inner mold 3000 contacts, the shape of the inner mold 3000 can change according to the shape of the step difference, enhancing the effect of sealing the cavity 3400.

As illustrated in FIGS. 9 and 10, in step S200, the upper mold 2000, the inner mold 3000, the target object, and the lower mold 1000 may be sequentially disposed. As the upper mold 2000, the inner mold 3000, and the lower mold 1000 move closer to one another with the target object in between, the mold unit MLD may be assembled. For example, the mold unit MLD and the display device 10 may be combined.

In the combined state of the mold unit MLD, the target object may be completely sealed by the mold unit MLD. For example, an upper surface 20a of the cover window 20 may contact the lower mold 1000, a side surface 20c of the cover window 20 may contact the inner surface of the second outer wall 3100, and a lower surface PCBa of the driver substrate PCB may contact the lower surface 3200a of the inner wall 3200. An upper surface PCBb of the driver substrate PCB may be in contact with the display module DM. Here, a surface is upper or lower for the driver substrate PCB and the cover window 20 is based on FIG. 5, and the driver substrate PCB and the cover window 20 are in an upside down position in FIGS. 8-14. Thus, the cavity 3400 may be completely sealed by the lower surface 20b of the cover window 20, the inner surface of the second outer wall 3100, the lower surface of the top plate 3300, and the outer surface of the inner wall 3200 along with the perimeter of the display device 10.

According to the mold unit MLD and the method S1 for manufacturing a display device, the lower surface 3200a of the inner wall 3200 contacting the lower surface PCBa of the driver substrate PCB may minimize damage caused by pressure on the display device 10. For example, by contacting the relatively strong driver substrate PCB, instead of the weaker cover panel 400 or cover spacer 500, the lower surface of the inner wall 3200 may minimize pressure damage to the display device 10.

The lower surface of the first outer wall 2100 of the upper mold 2000 is illustrated as contacting the upper surface of the base 1100 in the combined state of the mold unit MLD, but the present disclosure is not limited thereto. For example, in the combined state of the mold unit MLD, the lower surface of the first outer wall 2100 of the upper mold 2000 may not contact the upper surface of the base 1100.

The lower surface of the second outer wall 3100 of the inner mold 3000 is illustrating as not contacting the upper surface of the base 1100 of the lower mold 1000 in the combined state of the mold unit MLD, but the present disclosure is not limited thereto. For example, in the combined state of the mold unit MLD, the lower surface of the second outer wall 3100 of the inner mold 3000 may contact the upper surface of the base 1100 of the lower mold 1000.

As illustrated in FIG. 11, in step S300, the paste PST may be injected into the cavity 3400 using a head HD.

The head HD may be an injection device capable of injecting liquid paste PST, such as an inkjet device or a dispenser device.

The paste PST may include the aforementioned filler, which may contain at least one selected from among a cationic polymerizable compound, a cationic photopolymerization initiator, a phosphoric compound, or a carboxylic acid compound.

The paste PST may be discharged from the head HD and injected into the cavity 3400 through the inlet 3610. As the cavity 3400 surrounds the display device 10 along the inner wall 3200, the paste PST injected into the cavity 3400 may move clockwise and counterclockwise, filling the entire cavity 3400.

In an embodiment of the present disclosure, if the paste PST exceeds the volume of the cavity 3400, the excess may be discharged through the outlet 3620. Excess paste PST may remain in the inlet 3610 and the outlet 3620.

As illustrated in FIG. 12, in step S400, the paste PST may be photo-cured to form the outer structure 30. The photo-curing of the paste PST may use light in the ultraviolet (UV) or visible wavelength range. The photo-curing of the paste PST may be performed within about 1 minute, for example, within about 30 seconds to about 1 minute.

Here, the paste PST may contact the bending protection layer BPL of the display panel 100 and the cover panel 400, filling the cavity 3400. The bending protection layer BPL and the cover panel 400 contain an amine compound, but the basic amine may be neutralized by the phosphoric compound or carboxylic acid compound included in the paste PST, preventing the inhibition of photo-curing of the paste PST.

The excess paste PST remaining in the inlet 3610 and the outlet 3620 may form a tip 30_T.

As illustrated in FIG. 13, in step S500, the lower mold 1000, the target object, the inner mold 3000, and the upper mold 2000 may be disassembled and separated. The target object separated from the mold unit MLD may then be retrieved to a separate space for additional processing.

Thereafter, as illustrated in FIG. 14, in step S600, the tip 30_T on the outer structure 30 may be removed using a separate cutting device.

The tip 30_T is illustrated as overlapping with the outer structure 30 in the third direction DR3, but the present disclosure is not limited thereto. Alternatively, in an embodiment of the present disclosure, the tip 30_T may not overlap with the outer structure 30 in the third direction DR3. In this case, the inlet 3610 and the outlet 3620 may not overlap with the cavity 3400 in the third direction DR3. Thus, when removing the tip 30_T, a step difference on the lower surface of the outer structure 30 is prevented.

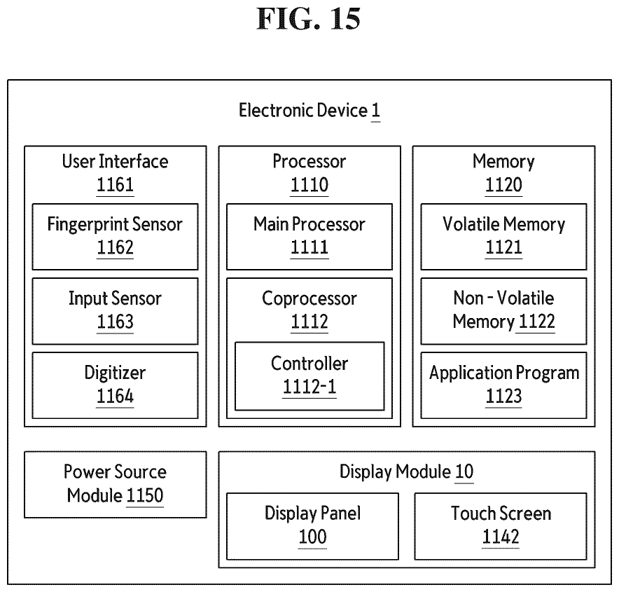

FIG. 15 is a diagram illustrating an electronic device according to an embodiment of the present disclosure. Referring to FIG. 15, the electronic device 1 according to an embodiment of the present disclosure may output various information (e.g., images, text, music, etc.) through a display device 10. When a processor 1110 executes an application stored in a memory 1120, the display device 10 may provide application information to a user through a display panel 100.

In an embodiment of the present disclosure, the electronic device 1 may be configured as a smartphone, camera, smart TV, monitor, smartwatch, tablet, automotive display, or AR/VR headset. For example, the electronic device 1 may be a smartphone including a touch-sensitive display area DA for interaction and a non-display area NDA including sensors and circuits for enhanced functionality. For example, the electronic device 1 may be a television or monitor including a large display area DA for high-resolution video playback and a non-display area NDA incorporating driving circuits or connectivity modules for external inputs. For example, the electronic device 1 may be a smartwatch including a display area DA optimized for compact and high-clarity visuals and a non-display area NDA integrating biometric sensors for health monitoring. In some cases, the electronic device 1 be an AR/VR headset.

In an embodiment of the present disclosure, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming (e.g. audiovisual) and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 100, the processor 1110 activates a camera module. The processor 1110 may transmit image data corresponding to a captured image acquired through the camera module to the display device 10. The display device 10 may display an image corresponding to the captured image through the display panel 100.

As another example, when a user wishes to make a phone call, the user taps the telephone icon displayed on the display device 10, the processor 1110 may execute a phone application program stored in the memory 1120. A telephone keypad may be presented on the display panel 100 for the user to enter a phone number to call.

As another example, the display device 10 may be integrated into an electronic device 1, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display device 10, and output image data. The controller 1112-1 may output various control signals to drive the display device 10. For example, the controller 1112-1 may drive the display device 10 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1 and input data or output data for commands related thereto. For example, a camera application program, a GPS application program, an augmented reality and virtual reality application program, and other application programs that can be executed by the processor 1110 upon selection of corresponding icons presented on the display screen (or display panel 100) via the touch screen 1142 or user interface 1161 by the user. In addition, various setting data corresponding to user settings may be stored in the memory 1120. The memory 1120 may include volatile memory 1121 and non-volatile memory 1122.

The display device 10 may output visual information (images) to the user. The display device 10 may include the display panel 100, a gate driver, the source driver, a voltage generation circuit, and a touch screen 1142. The display device 10 may further include a window, a chassis, and a bracket to protect the display panel 100.

The user interface 1161 serves as the interaction medium between a user and the electronic device 1. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 100.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 100 through a continuous process with a process of forming elements (for example, the light emitting element, the transistor, and the like) included in the display panel 100.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 100 to sense pressure applied to the top layer (screen) of the display panel 100. The touch sensors can be a capacitive or a resistive type. The touch screen 1142 may serve as the primary interface for the user to select and navigate applications, control, and interact with the electronic device 1.

The display panel 100 (or display) may include a liquid crystal display panel, an organic light emitting display panel, or an inorganic light emitting display panel, and the type of the display panel 100 is not particularly limited. The display panel 100 may be of a rigid type or a flexible type that can be rolled or folded. The display device 10 may further include a supporter, bracket, heat dissipation member, and the like that support the display panel 100.

The power source module 1150 may supply power to the components of the electronic device 1. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display device 10.

In concluding the detailed description, those skilled in the art will appreciate that many variations and modifications may be made to the specific embodiments described above without departing from the spirit and scope of the present disclosure as defined in the appended claims. Therefore, the disclosed specific embodiments of the present disclosure are used in a generic and descriptive sense only and not for purposes of limitation.

What is claimed is:

1. A display device comprising:
a display module, the display module including a display panel;
a driver substrate connected to the display module;
a bending protection layer disposed on one surface of the display panel; and
an outer structure surrounding the driver substrate and the bending protection layer,
wherein a filler composition for fabricating the outer structure includes a cationic polymerizable compound, a cationic photopolymerization initiator, and at least one selected from a phosphoric compound or a carboxylic acid compound.

2. The display device of claim 1, wherein the cationic polymerizable compound includes a cyclic compound having an epoxy group and an aromatic compound having an epoxy group.

3. The display device of claim 2, wherein
the aromatic compound having an epoxy group includes a bisphenol A-type epoxy resin and a bisphenol F-type epoxy resin, and
a mass ratio of the bisphenol A-type epoxy resin to the bisphenol F-type epoxy resin is from about 0.2 to about 5.

4. The display device of claim 1, wherein the phosphoric compound includes at least one selected from among compounds represented by Chemical Formulas 1 through 4: 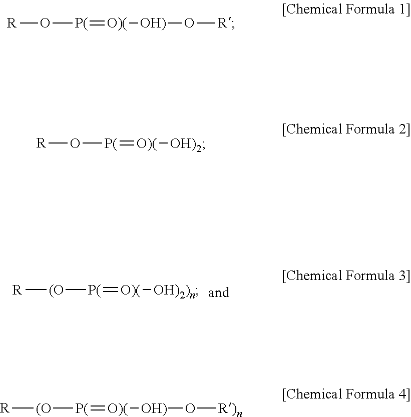
wherein
R and R′ are each independently a substituted or unsubstituted hydrocarbon group, and
n is from 2 to 10.

5. The display device of claim 1, wherein the carboxylic acid compound includes at least one selected from among compounds represented by Chemical Formulas 5 and 6: 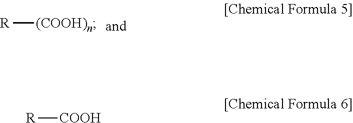
wherein
R is each independently a substituted or unsubstituted hydrocarbon group, and
n is from 2 to 10.

6. The display device of claim 1, wherein the phosphoric compound or the carboxylic acid compound is included in an amount of about 0.1 to about 5 parts by mass per 100 parts by mass of the cationic polymerizable compound.

7. The display device of claim 1, wherein the cationic photopolymerization initiator includes at least one selected from among a sulfonium salt, an iodonium salt, or an onium salt other than the sulfonium salt and the iodonium salt.

8. The display device of claim 1, wherein the cationic photopolymerization initiator is included in an amount of about 0.05 to about 50 parts by mass per 100 parts by mass of the cationic polymerizable compound.

9. The display device of claim 1, wherein
the phosphoric compound includes a phosphoric ester, and
a molecular weight of the phosphoric ester is about 400 or less.

10. The display device of claim 1, wherein a viscosity of the filler composition is from about 1,000 cps to about 20,000 cps.

11. A method for manufacturing a display device that comprises a display module including a display panel, a driver substrate connected to the display module, and a bending protection layer disposed on one surface of the display panel, the method comprising:
combining a mold unit and the display device;
injecting a paste through an inlet of the mold unit; and
curing the paste to form an outer structure,
wherein the paste includes a cationic polymerizable compound, a cationic photopolymerization initiator, and at least one selected from a phosphoric compound or a carboxylic acid compound.

12. The method of claim 11, wherein the paste is photo-cured.

13. The method of claim 12, wherein the photo-curing of the paste is performed for about 30 seconds to about 1 minute.

14. The method of claim 11, wherein the paste contacts the bending protection layer.

15. The method of claim 11, wherein the cationic polymerizable compound includes a cyclic compound having an epoxy group and an aromatic compound having an epoxy group.

16. The method of claim 15, wherein
the aromatic compound having an epoxy group includes a bisphenol A-type epoxy resin and a bisphenol F-type epoxy resin, and
a mass ratio of the bisphenol A-type epoxy resin to the bisphenol F-type epoxy resin is from about 0.2 to about 5.

17. The method of claim 11, wherein the phosphoric compound includes at least one selected from among compounds represented by Chemical Formulas 1 through 4: 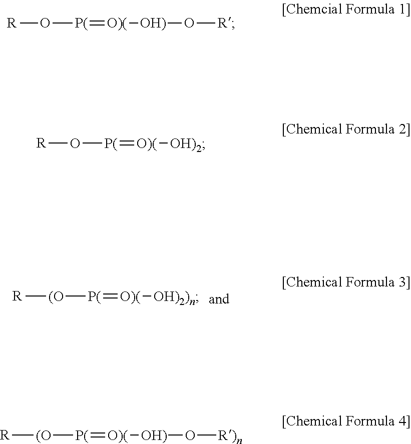
wherein
R and R′ are each independently a substituted or unsubstituted hydrocarbon group, and
n is from 2 to 10.

18. The method of claim 11, wherein the carboxylic acid compound includes at least one selected from among compounds represented by Chemical Formulas 5 and 6: 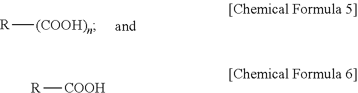
wherein
R is each independently a substituted or unsubstituted hydrocarbon group, and
n is from 2 to 10.

19. The method of claim 11, wherein the phosphoric compound or the carboxylic acid compound is included in an amount of about 0.1 to about 5 parts by mass per 100 parts by mass of the cationic polymerizable compound.

20. An electronic device, comprising:
a processor;
a memory having stored application programs for execution by the processor;
a display device including a display panel and receiving data from the processor to display image; and
a user interface configured to sense user input via touch or cursor select of an icon presented on the display panel, wherein the processor is caused to execute one or more of the stored application programs upon receipt of the user input,
wherein the display device comprises:
a display module, the display module including the display panel;
a driver substrate connected to the display module;
a bending protection layer disposed on one surface of the display panel; and
an outer structure surrounding the driver substrate and the bending protection layer,
wherein a filler composition for fabricating the outer structure includes a cationic polymerizable compound, a cationic photopolymerization initiator, and at least one selected from a phosphoric compound or a carboxylic acid compound.
